(19) United States
(12) Patent Application Publication
(10) Pub. No.: US 2015/0061719 A1
(43) Pub. Date: Mar. 5, 2015

(54) VERTICAL PROBE CARD FOR MICRO-BUMP PROBING

(71) Applicant: soulbrain ENG Co., Ltd., Seoul (KR)

(72) Inventors: Jae Hwan LEE, Seoul (KR); Sang Jin PARK, Seoul (KR); Ki Chea YOON, Seoul (KR)

(73) Assignee: soulbrain ENG Co., Ltd., Seoul (KR)

(21) Appl. No.: 14/278,136

(22) Filed: May 15, 2014

(30) Foreign Application Priority Data
Sep. 5, 2013 (KR) 10-2013-0106794
Jan. 27, 2014 (KR) 10-2014-0009918

(51) Int. Cl. G01R 1/073

(52) U.S. Cl. CPC G01R 1/07307
USPC 324/756.03

(57) ABSTRACT

The present invention relates to a probe card, and more particularly a probe card that can provide fine pitch for micro-bump probing, can be manufactured at a low cost for a short time through a simple manufacturing process, and can have excellent electric characteristics because it can have the components and a thin film resistance therein.

### CROSS-REFERENCE TO RELATED APPLICATIONS

Pursuant to 35 U.S.C. §119(a), this application claims the benefit of earlier filing date and right of priority to Korean Patent Application No. 10-2013-0106794, filed on 5 Sep. 2013, and No. 10-2014-0009918, filed on 27 Jan. 2014, the contents of which are incorporated by reference herein in their entirety.

### BACKGROUND

1. Field

The present invention relates to a probe card, and more particularly a probe card that can provide fine pitch, can be manufactured at a low cost for a short time through a simple manufacturing process, and can have excellent electric properties because it can have the components and a thin film resistance therein.

Further, the present invention relates to a vertical probe card for micro-bump probing which is brought in electric contact with the micro-bump of a circuit element when performing electrical test on the circuit element.

2. Related Art

Semiconductor chips manufactured in wafer undergoe EDS (Electrical Die Storing) for testing electric properties by LCDs (Liquid Crystal Display), testers equipped with various measurers before assembled in a semiconductor package, or probe equipment with a probe card that can be brought in electric contact with a semiconductor chip that is the object.

The probe card includes a printed circuit board receiving electric signals from a tester with a plurality of probe tips that are brought in contact with a contact pad on an object to be tested (wafer) and a space transformer disposed between the probe tips and transmitting test signals by connecting the printed circuit board with the probe tips.

FIGS. 1 and 2 are vies showing a probe card of the related art.

First, FIG. 1 shows a space transformer type of probe card using metal wires, in which micros-holes are formed in a space transformer substrate 20 between a printed circuit board 10 and probe tips 40 and then wires 30 connecting the printed circuit board 10 with the probe tips 40 are inserted and fixed in the micro-holes.

The space transformer type of probe card using wires has the advantage that it can be manufactured for a short time and the manufacturing cost is low, but there is a problem in that it is difficult to mount components in the space transformer, so the voltage drops accordingly, and a problem in that the lengths of the wires are different, so electric signals are differently received.

FIG. 2 shows an MLC (Multi-Layer Ceramic)/MLO (Multi-Layer Organic) space transformer type of probe card. For example, the multi-layer ceramic substrate 50 between a printed circuit board 10 and probe tips 40 has a multilayer therein, such that it can have uniformity in length and better circuit characteristics in comparison to the wire types. However, there is a defect that the manufacturing process is complicated, the manufacturing time is long, and the manufacturing cost is high.

Further, recently, circuit patterns are integrated with high density on wafers with an increase in demand of high integrated semiconductor chips, such that the gaps between adjacent contact pads, that is, the pitch is very small, and accordingly, the probe tips of the probe card for testing the contact pads are required to be formed with fine pitch, but it is difficult to implement micro scale manufacturing in the probe cards of the related art.

For example, “Probe card and method of manufacturing the probe card” has been proposed in Patent Document 1 (Korean Patent Publication No. 10-2013-0072396) in order to solve the problems, but there is no effect than expected in Patent Document 1.

Further, recently, as the bumps of circuit boards become minute with development in packaging such as the TSV (Through Silicon Via), it is required to achieve fine pitch and minimize damage to the micro-bumps in probing, in the electrical test on circuit elements.

However, it is not easy to manufacture a probe card by which it is possible to achieve fine pitch and minimize damage to bumps, and even if it is possible to manufacture the probe card, the manufacturing cost may remarkably increase.

### SUMMARY

The present invention has been made in an effort to provide a probe card, and more particularly a probe card that can provide fine pitch, can be manufactured at a low cost for a short time through a simple manufacturing process, and can have excellent electric properties because it can have the components and a thin film resistance therein.

A probe card according to an aspect of the present invention includes: a printed circuit board; a space transformer substrate that has a first side facing the printed circuit board and a second side opposite to the first side, has first circuit patterns on the second side, and has conductive signal transmitting portions that are filled in a plurality of through-holes formed through the first side and the second side and are connected with the first circuit pattern; a plurality of connectors that connect the printed circuit board with the signal transmitting portions of the space transformer substrate; and probe tips that has one end that can be brought in contact with an object to be tested and the other end that is connected to the first circuit patterns of the space transformer substrate.

The space transformer substrate may be made of ceramic.

According to another embodiment of the present invention, a probe card includes: a printed circuit board; a multilayer ceramic substrate that is disposed away from the printed circuit board and composed of several pattern layers; a pattern substrate that is coupled to the multilayer substrate and has first circuit patterns on the opposite side to the side coupled to the multilayer ceramic substrate; a plurality of connector that connect the printed circuit board with the multilayer ceramic substrate or the printed circuit board with the pattern substrate; and probe tips that have one end that can be brought in contact with an object to be tested and the other end connected to the multilayer ceramic substrate or the pattern substrate.

The multilayer ceramic substrate may have second circuit patterns formed on the side facing the printed circuit board, and the connectors may connect the second circuit patterns with the printed circuit board.

The connectors may be any one of metal rods or metal wires or combinations of both of metal rods and metal wires.

The first circuit patterns may be formed in a shape corresponding to the probe tips, depending on any one or both of the arrangement of the probe tips and gaps therebetween.

The first circuit patterns may be formed such that the distances from contact points that the probe tips are in contact with to signal transmitting portions.

The printed circuit board may be protected by a reinforcing panel.

The first circuit patterns may be formed by MEMS (Micro Electro Mechanical System).

In the vertical probe card for probing a micro-bump according to embodiments of the present invention, the probe tip may have: a contact portion that is brought in electric contact with a micro-bump of a circuit device; a transmitting portion that is disposed at the opposite side to the contact portion to interface an electric signal generated by electric contact with the micro-bump to a substrate thereon; a connecting portion that has a vertical pole structure to connect the contact portion with the transmitting portion; and protrusions that are formed to protrude from the surface of the vertical pole structure toward the micro-bump, at the corners of the end of the contact portion.

When the protrusions separately protrude or have a cuboid pole structure, two corners of four corners of the end of the contact portion may be connected and the other two corners may be separated.

The contact portion may be made of a nickel ally or a copper alloy and the end of the contact portion may be made of rhodium or, carbon and rhodium on the end surface coating.

The probe card may further include a first guide having a through-hole through which the contact portion passes to expose the contact portion at a predetermined height.

The first guide may include mechanical machining ceramic and a silicon substrate and through-hole of the silicon substrate may be formed by Fabrication process

A coating layer may be formed on the side of the through-hole of the silicon substrate by coating the side with an insulator.

When the first guide is further included, the connector may have an S-shaped bending structure.

The probe card may further include a second guide having a through-hole through which the contact portion passes to expose the end of the transmitting portion.

The second guide may include mechanical machining ceramic and a silicon substrate and through-hole of the silicon substrate may be formed by Fabrication process.

The substrate on the transmitting portion is a single-layer silicon substrate, a multilayer silicon substrate, or a multilayer silicon substrate and a stacked ceramic substrate and may have an electric wire connected from one side to the other side.

At least any one of the contact portion, the transmitting portion, the connecting portion, and the protrusions may be made of a different from that of at least another one of the contact portion, the transmitting portion, the connecting portion, and the protrusions.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention.

FIGS. 1 and 2 are vies showing a probe card of the related art.

FIG. 3 is a view showing a probe card according to a first embodiment of the present invention.

FIGS. 4 to 5b are views showing the first side and the second side of the space transformer substrate shown in FIG. 3.

FIG. 6 is a view showing a probe card according to a second embodiment of the present invention.

FIG. 7 is a view showing a probe card according to a third embodiment of the present invention.

FIG. 8 is a schematic view illustrating a vertical probe card for micro-bump probing according to an embodiment of the present invention.

FIG. 9 is a view showing an example of the vertical probes of FIG. 8.

FIGS. 10 to 12 are views showing examples of the protrusion of FIG. 9.

FIG. 13 is a view showing another example of the vertical probes of FIG. 8.

FIG. 14 is a view illustrating an example of the guide of FIG. 8.

FIGS. 15 to 17 are views showing other embodiments of the vertical probe of FIG. 8.

### DETAILED DESCRIPTION OF THE PREFERRED EMBODIMENT

Arrangements and embodiments may now be described more fully with reference to the accompanying drawings, in which exemplary embodiments may be shown. Embodiments may, however, be embodied in many different forms and should not be construed as being limited to embodiments set forth herein; rather, embodiments may be provided so that this disclosure will be thorough and complete, and will fully convey the concept to those skilled in the art.

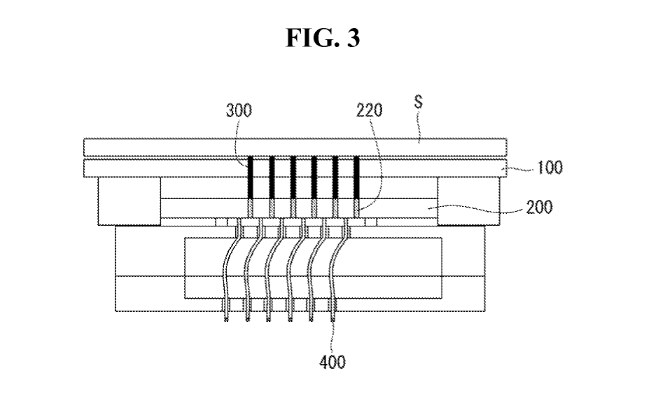

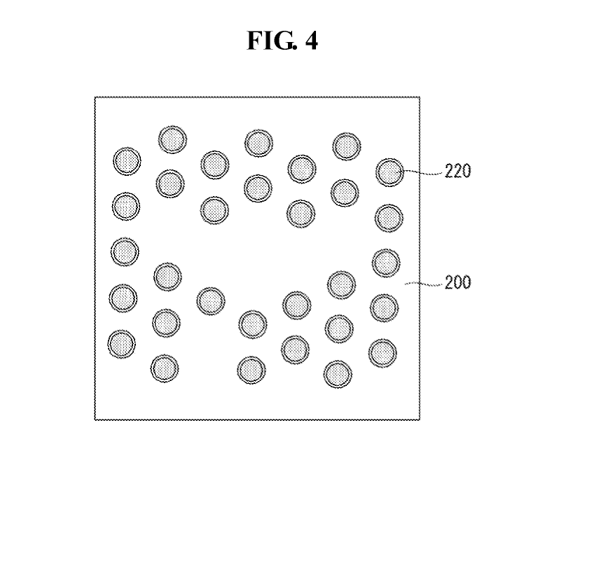

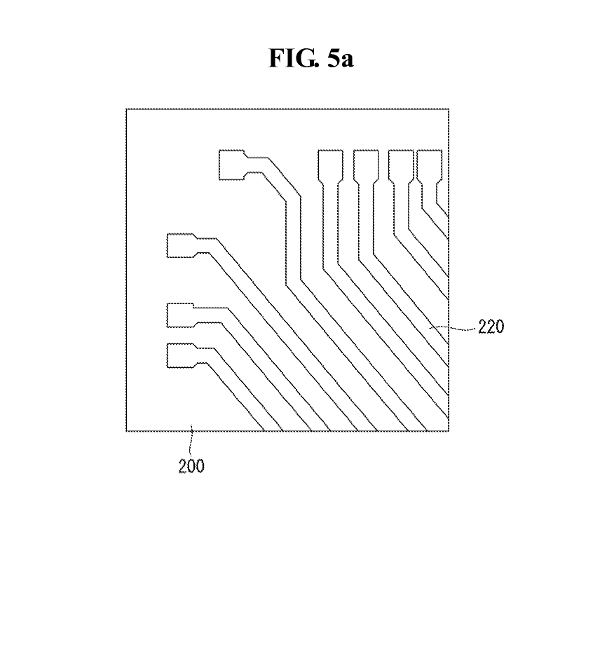

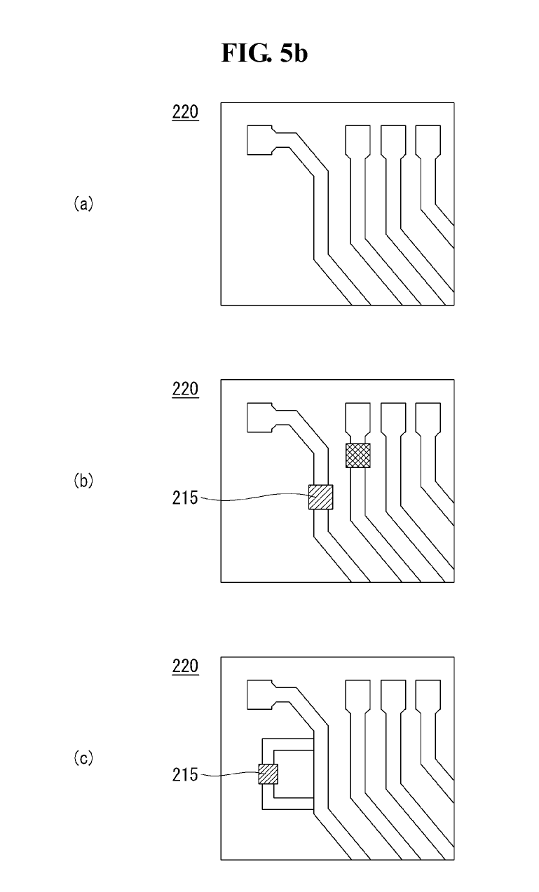

FIG. 3 is a view showing a probe card according to a first embodiment of the present invention and FIGS. 4 to 5b are views showing the first side and the second side of the space transformer substrate shown in FIG. 3.

Referring to FIGS. 3 to 5b, a probe card according to the first embodiment of the present invention, largely, includes a printed circuit board 100, a space transformer substrate 200, connectors 300, and probe tips 400.

The printed circuit board 100 is formed in the shape of a disc or a rectangular plate and has a top and a bottom opposite to the top. Probe circuit patterns (not shown) for a test are formed on the top and connected with a tester (not shown). In a test on a high integrated wafer, the gap between probe patterns on the top of the printed circuit board 100 may become very narrow and interference may be generated between the probe circuit patterns by the current flowing through the adjacent probe patterns. Accordingly, it is possible to form grooves (not shown) between adjacent probe patterns in order to prevent interference between the probe patterns. The printed circuit board 100 is protected against external shock by a reinforcing panel S.

The space transformer substrate 200 may be made of ceramic, glass, or silicon and a ceramic insulating substrate The space transformer substrate 200 has a first side facing the printed circuit board 100 and a second side opposite to the first side and a plurality of through-holes is formed through the first side and the second side by a tool such as a punch (not shown). Signal transmitting portions 220 are formed by filling a conductor such as Ni, Au, Ag, or Cu or forming thin films in the through-holes. A first circuit pattern 210 is formed to be connected with the signal transmitting portions 220 on the second side. The first circuit pattern 210 can be formed by MEMS (Micro Electro Mechanical System) fabrication and it is formed in a shape corresponding to the probe tips 400 in accordance with any one or both of the arrangement and gaps of the probe tips 400 to be described below so that the differences between the gaps of the terminals of the printed circuit board 100 and the gaps of the probe tips 400 can be compensated.

The connectors 300, which are components disposed between the printed circuit board 100 and the space transformer substrate 200, electrically connect the probe tips 400, which are connected with the first circuit pattern 210, with the probe circuit pattern on the printed circuit board 100 by connecting the probe circuit pattern on the printed circuit board 100 with the signal transmitting portions of the space transformer substrate 200. In the first embodiment of the present invention, metal rods are used as the connectors 300 and they may have predetermined elasticity. The connectors 300, which are metal rods, may be bonded to be fixed between the printed circuit board 100 and the space transformer substrate 200.

The probe tips 400 are a plurality of components that protrudes outside. Predetermined ends of the probe tips 400 can be elastically brought in contact with an object (wafer) and the other ends are connected to the first circuit pattern 210 of the space transformer substrate 200 in a test. The probe tips 400 can also be formed by MEMS fabrication.

As shown in FIG. 5a, circuit patterns 220 can be formed on the space transformer substrate 200, as described above. The signal patterns 210 may be circuits.

The signal patterns 210 may be provided in consideration of the transmission paths of signals. For example, they may be formed in consideration of paths to another circuit across the space transformer substrate 200 from the probe tips 400, and/or across the printed circuit board 100 from the probe tips 400, and/or across the printed circuit board 100 from the probe tips 400.

The paths can be formed such that the entire electric characteristic of each signal pattern 210 is uniform. For example, it means that the entire resistances between the first signal pattern 210a and the second signal pattern 210b are substantially the same. This will be understood clearly, when it is considered that when the resistance from the probe tips 400 to the printed circuit board 100 is different for each of the signal patterns 210, the electric signals transmitted to the printed circuit board 100 may be different even if the electric signals measured at the probe tips 400 are the same.

The lengths, thicknesses, and/or materials of the signal patterns 210 may be different for a uniform characteristic of the signal patterns 210. It means, for example, the length, thickness, and/or material of the first signal pattern 210a may be different from the length, thickness, and/or material of the second signal pattern 210b.

As shown in FIG. 5b, electric devices 215 may be mounted on the signal patterns 210.

Signal patterns 210 without a specific electric device 215 is shown in (a) of FIG. 5b.

Signal patterns 210 with an electric device 215 on their paths are shown in (b) of FIG. 5b. As shown in the figure, the electric devices 215 can be disposed on the signal patterns 210. Accordingly, there may be no need of additional spaces for the electric devices 215. Further, the electric devices 215 can be mounted at a lower cost than when the electric devices 215 are disposed in a multilayer structure.

Signal patterns 210 with an electric device 215 in empty spaces VS are shown in (c) of FIG. 5b. Since the electric devices 215 can be mounted on the empty spaces VS between the signal patterns 210, an effect of increasing the spatial usability can be expected.

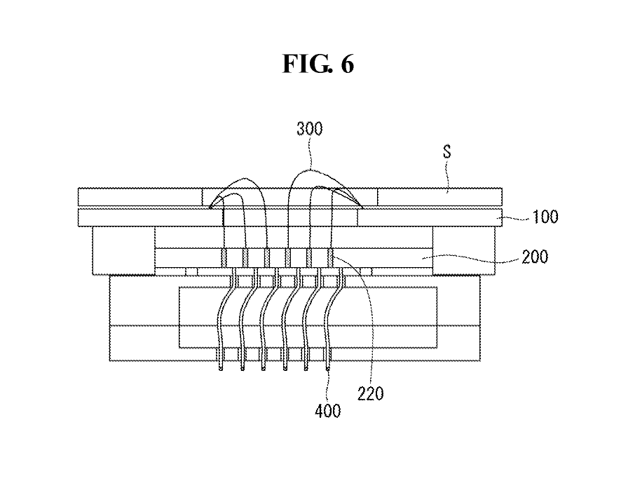

FIG. 6 is a view showing a probe card according to a second embodiment of the present invention.

As shown in FIG. 6, the probe card according to the second embodiment of the present invention is almost similar to the first embodiment, but it is discriminated in that the type of the connectors 300 is different.

That is, the connectors 300 used in the second embodiment of the present invention are metal wires, unlike the first embodiment using metal rods. Further, the connectors 300 may be implemented by both of metal rods and metal wires.

When the connectors 300 are metal wires, as described above, bonding for fixing the connectors 300 can be removed, such that they can be separately handled with ease, when there is a problem.

Further, when metal wires are used for the connectors 300, the lengths are different, so electric signals may be differently received. Accordingly, it can be compensated by forming the first patterns 210 on the second side of the space transformer substrate 200 such that the distances from the contact points of the probe tips 400 to the signal transmitting portion are uniform, for example, as shown in FIG. 4, by forming one of them substantially straight such that the distances from the contact points to the signal transmitting portion 220 is short, forming another one in the shape of a circle such that the distances are longer, and forming another one in the shape of a rectangle such that the distances are further longer. It is possible to increase the electrical characteristics by mounting various circuit parts (for example, a capacitance, and a resistor) or a thin film resistance, using a MEMS process, in the other areas without the patterns on the second side of the space transformer substrate 200 with the first circuit patterns 210 formed by MEMS (for example, exposing and etching) fabrication. Obviously, the first circuit patterns 210 may be applied not only to the second embodiment, but the first embodiment and the following third embodiment.

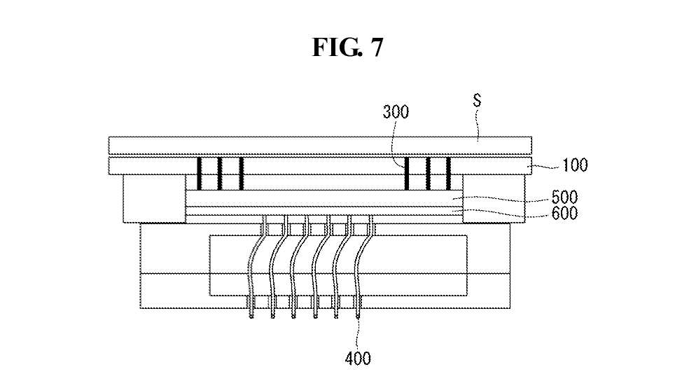

FIG. 7 is a view showing a probe card according to a third embodiment of the present invention.

As shown in FIG. 3, the probe card according to the third embodiment of the present invention is different from the first and second embodiments using the space transformer substrate 200 in that a multilayer ceramic substrate 500 and a pattern substrate 600 are used.

The multilayer ceramic substrate 500, a component disposed away from the printed circuit board 100, is composed of several pattern layers formed by disposing conductive layers and insulating layers alternately several times on an insulating substrate. The printed circuit board 100 and the probe tips 400 can be electrically connected even by the multilayer ceramic substrate 500. The multilayer ceramic substrate 500 used in the present invention is a lower-layered ceramic substrate in comparison to multilayer ceramic substrates 500 of the related art, so the manufacturing time and the manufacturing cost can be reduced.

The pattern substrate 600, which is a component combined with the multilayer ceramic substrate 500, has first circuit patterns 210 on the side opposite to the side facing the multilayer ceramic substrate 500, and it may be formed by stacking wafers or polyamides. The first circuit patterns 210 on the pattern substrate 600 are the same as those described in the first and second embodiments, so they are not described.

The connectors 300 used in the third embodiment electrically connect the printed circuit board 100 with the probe tips 400 connected to the first circuit patterns 210 of the pattern substrate 600 by connecting the printed circuit board 100 with the multilayer ceramic substrate 500. The connectors 300 are preferably metal rods.

Although FIG. 7 shows that the pattern substrate 600 is coupled to the bottom of the multilayer ceramic substrate 500, it may be coupled to the top of the multilayer ceramic substrate 500 or a pattern substrate 600 may be coupled to both of the top and the bottom of the multilayer ceramic substrate 500, if necessary. Accordingly, the connectors 300 connect the printed circuit board 100 with the multilayer ceramic substrate 500 or the printed circuit board 100 with the pattern substrate 600, depending on the coupling type of the pattern substrate 600.

Second circuit patterns (not shown) may be formed on the side of the multilayer ceramic substrate 500 which faces the printed circuit board 100. The second circuit patterns 600 are the same as the first circuit board 210, except for the positions. In this case, the connectors 300 between the printed circuit board 500 and the multilayer ceramic substrate 500 connect the second circuit patterns with the printed circuit board 100. As described above, since the connectors 300 can be freely arranged, when the second circuit patterns are formed, various designs can be freely achieved.

Through this configuration, fine pitch (about 80 um or less) can be achieved, that the multilayer ceramic substrate 500 can be used in common, that is, it is possible to reduce the manufacturing time and cost of the space transformer by manufacturing and storing in advance the part to be designed in a multilayer structure into a low layer that can be easily manufactured when manufacturing the multilayer ceramic substrate 500 and then by separately designing needed parts when manufacturing a probe card.

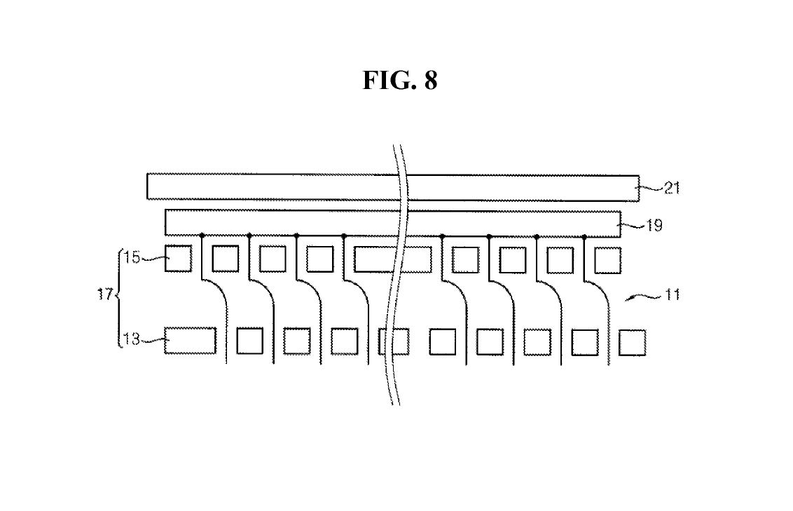

FIG. 8 is a schematic view illustrating a vertical probe card for micro-bump probing according to an embodiment of the present invention.

Referring to FIG. 8, the probe card 100 of the present invention includes a first substrate 19, a second substrate 21, a guide unit 17 composed of first guides 13 and second guides 15, and vertical probes 11. Further, though not shown in the figure, the probe card 100 of the present invention may further include a flatness adjusting unit that adjusts flatness, a coupling portion that couples the first substrate 19 and the second substrate 21, a reinforcing unit that structurally reinforces the first substrate 19 and the second substrate 21, a connecting unit that electrically connects the first substrate 19 and the second substrate 21, and a coupling unit that couples the first guides 13 and the second guides 15.

The first substrate 19 may be referred as a space transformer) and a plurality of vertical probes 11 that can be electrically connected with circuit devices such as a semiconductor device can be brought in electric contact with one side of the first substrate 19. The first substrate 19 may be a single-layer silicon substrate, a multilayer silicon substrate, or a multilayer silicon substrate and a stacked ceramic substrate. That is, the first substrate 19 may have a single layer of silicon substrate, several layers of silicon substrates, or several layers of silicon substrates and stacked ceramic substrates. Further, the first substrate 19 may have an electric wire connected from one side to the other side, and particularly, it may have an electric wire expanding from one side to the other side.

The second substrate 21, which may have a printed circuit board (PCB), may have a structure in which it is electrically connected to the other side of the first substrate 19. Further, the second substrate 21 may have a structure in which it is electrically connected with an external device such as a test controller.

Accordingly, in an electrical test on a circuit device using the probe card 100 of the present invention, electric signals interfaced to a test controller through the first substrate 19 and the second substrate 21 by electrically connecting the vertical probes 11 to the circuit device are used.

The vertical probes 11 included in the probe card 100 of the present invention are described hereafter. The vertical probes 11 have a vertical pole structure and are not limited to the shape. However, considering the structural stability, the vertical probes 11 of the present invention may have various structures, particularly, a cuboid pole structure.

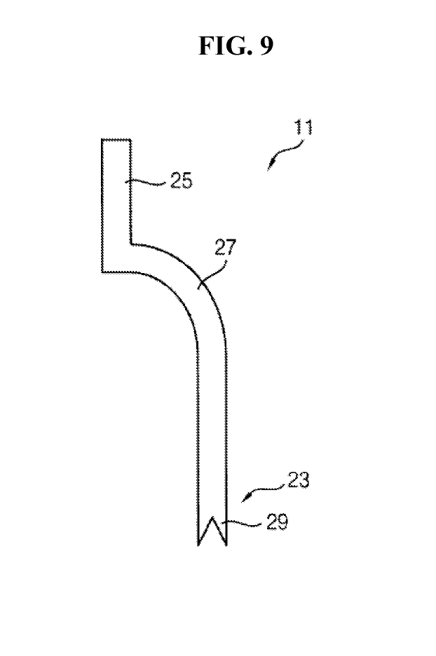

FIG. 9 is a view showing an example of the vertical probes of FIG. 8.

Referring to FIG. 9, the vertical probe 11 of the present invention, which has a cuboid pole structure, may have a contact portion 23, a transmitting portion 25, and a connecting portion 27. A protrusion 29 may be formed at the end of the contact portion 23.

The contact portion 23, which is a part that is brought in electric contact with a circuit device when an electrical test is performed on the circuit device, maintains stable electric contact with a micro-bump of the electric circuit, using the protrusion 29 at the end of the contact portion 23.

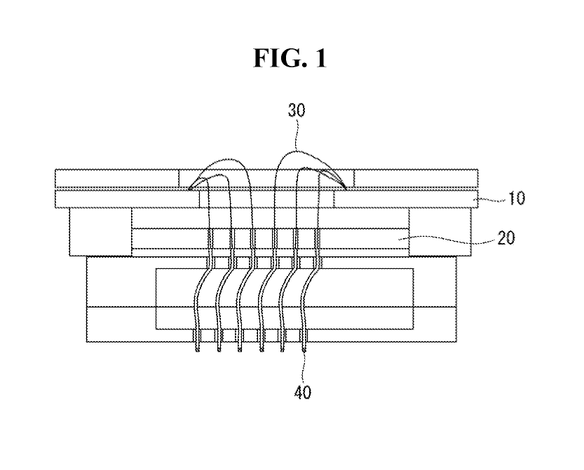

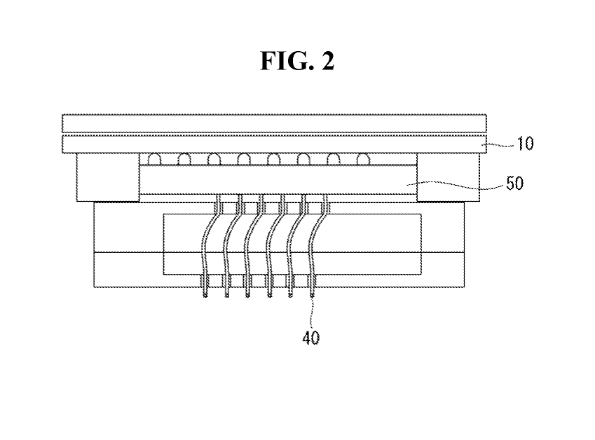

The transmitting portion 25 may be disposed at the opposite side to the contact portion 23 to interface an electric signal, which is generated by electric contact with the circuit device, to the substrate thereon. That is, the transmitting portion 25 may be disposed at the opposite end to the contact portion 23, in the vertical probe 11. The substrate that can be electrically interfaced to the transmitting portion 25 may be considered as the first substrate 19 in FIG. 1. The transmitting portion 25 and the first substrate 19 can be electrically interfaced by electric connection between the transmitting portion 25 and the pad on one side of the first substrate 19.

The connecting portion 27 may connect the contact portion 23 and the transmitting portion 25. Accordingly, since the contact portion 23 and the transmitting portion 25 are connected by the connecting portion 27, the vertical probe 11 having the integrated structure of the contact portion 23, the connecting portion 27, and the transmitting portion 25 can be achieved.

The vertical probe 11 of the present invention can have a vertical cuboid pole structure, as described above, and particularly, the connecting portion 27 may have a curved structure to reduce damage to a micro-bump of a circuit device using the vertical probe 11 by attenuating a pressing force generated by the vertical probe 11 when it is brought in electric contact with the micro-bump of the circuit device.

The protrusion 29, which is formed at the end of the contact portion 23, as described above, can be brought in electric contact with a micro-bump of a circuit device in an electrical test on the circuit device. In the cuboid pole structure that is the surface of the end of the contact portion 23, four corners may protrude toward the micro-bump of the circuit device.

Hereafter, the protrusion 29 is described in more detail.

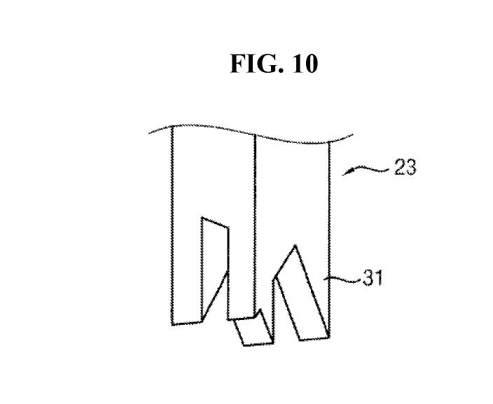

FIGS. 10 to 12 are views showing examples of the protrusion of FIG. 9.

Referring to FIG. 10, first, the protrusion 31 may have a structure with four corners protruding from the surface of the end of the contact portion 23 having a cuboid pole structure, in which the portions protruding from two of the four corners may be connected with each other and the other portions protruding from the other two corners may be separated. That is, the protrusions 31 may be separated at one side and the other side with the center of the end surface of the contact portion 23 therebetween and they are connected at the one side and the other side, respectively.

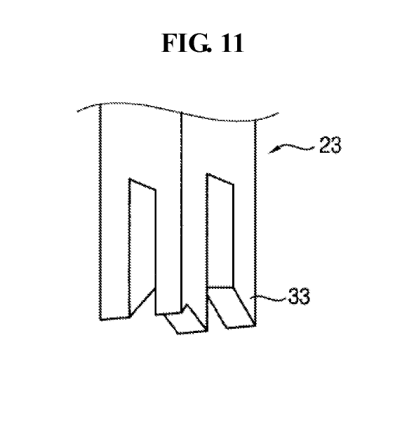

Referring to FIG. 11, protrusions 33 may have a structure in which the portions protruding at four corners are separated. That is, the protrusions 33 may separately protrude at four corners.

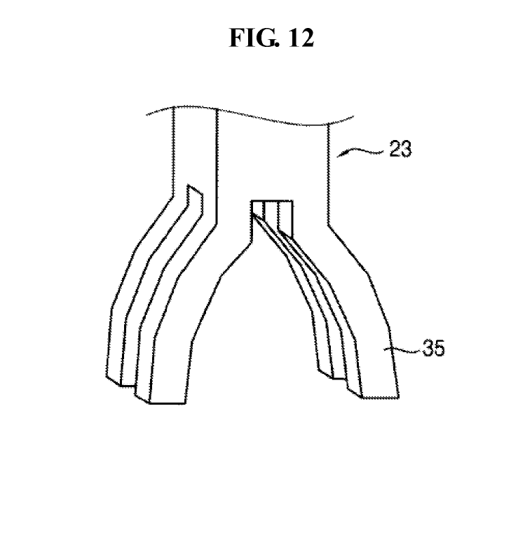

Referring to FIG. 12, protrusions 35 may protrude separately from four corners, opening outward from the end surface of the contact portion 23.

As described above, the protrusions 31, 33, and 35 may protrude from the end of the contact portion 23 in various structures, in the vertical probes 11 of the present invention.

Referring to FIG. 9 again, the contact portion 23 may be made of a nickel alloy or a copper alloy that has relatively high electric conductivity and elasticity may be used in consideration of manufacturability and a rhodium alloy or a carbon-plated material and a rhodium-plated material may be used for the protrusions 29 in consideration of high durability when the protrusions come in contact with the micro-bump of a circuit device. When different materials are used, the contact portion 23 and the protrusions 29 each may be manufactured by making them using different materials and then hybrid-combing them, or the protrusions 23 may be coated with a carbon alloy and a rhodium alloy.

In particular, in the vertical probes 11 of the present invention, the protrusions 29, the contact portion 23 connected with the protrusions 29, the connecting portion 27, and the transmitting portion 25, at one side and the other side from the center of the end surface of the contact portion 23 where the protrusions 29 are formed may be made of a nickel alloy that is useful for MEMS, and the contact portion 23, the connecting portion 27, and the transmitting portion 25 at other portions without the protrusions 29 may be manufactured by making them using a copper alloy having high electric conductivity and elasticity and then hybrid-combining them. That is, in the present invention, the vertical probes 11 can be manufactured in a 2D structure by MEMS and then hybrid-combined into a 3D structure.

As described above, since the vertical probes 11 of the present invention can be manufactured into a 2D structure or a 3D structure by MEMS process, a micro-structure can be achieved. Accordingly, the probe card 100 including the vertical probes 11 of the present invention can be more actively applied to an electrical test on recent circuit devices with fine pitch.

Further, in the vertical probes 11 of the present invention, the protrusion 23 that comes in electric contact with the connection terminal of a circuit device can be selectively made of a material having has high durability and high strength and the other portions can be selectively made of a material having high electric conductivity and elasticity, such that it is possible to ensure durability of the vertical probes 11 and minimize damage to the micro-bump of a circuit device that comes in contact with the vertical probes 11.

Further, since the protrusion 29 of the present invention can have a structure surrounding the micro-bump of a circuit device, they can be protected to be naturally aligned in the probing direction when coming in contact with a circuit device. In addition, since the protrusions 29 can be made of a carbon and rhodium-plated material having high hardness, as described above, electric contact and durability can be improved in probing of a micro-bump.

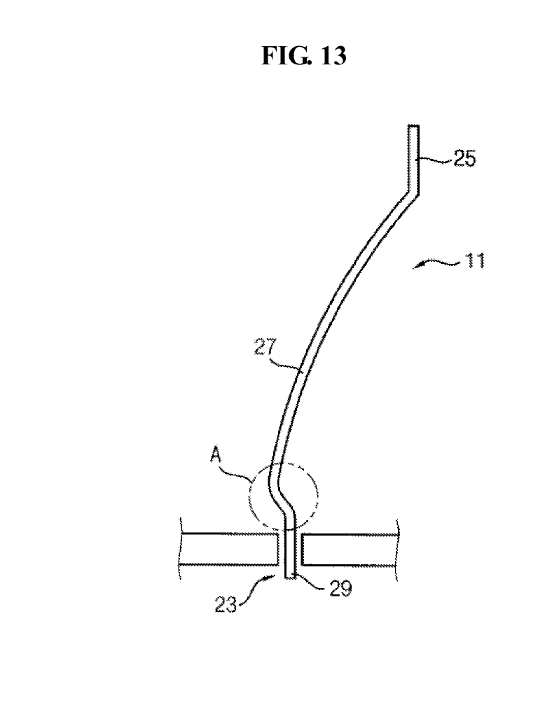

FIG. 13 is a view showing another example of the vertical probes of FIG. 8.

Referring to FIG. 13, the connecting portion 27 of the vertical probe 11 of the present invention is shown, in which the connecting portion 27 may have a curved structure, as described above. In particular, the connecting portion 27 may have a double curve at the portion ‘A’. In other words, the connecting portion 27 may have an S-shaped structure.

As described above, forming the connecting portion 27 in an S-shaped structure with a double curve is because when the protrusions 29 are brought in contact with a micro-bump and vertical stress is applied to the contact portion 23, the connecting portion 27 of the contact portion 23 moves horizontally and may be damaged accordingly due to contact with the first guide 13.

Accordingly, in the present invention, when the probe card 100 has the first guide 13, contact between the connecting portion 27 and the first guide 13 is prevented by forming the connecting portion 27 in an S-shape.

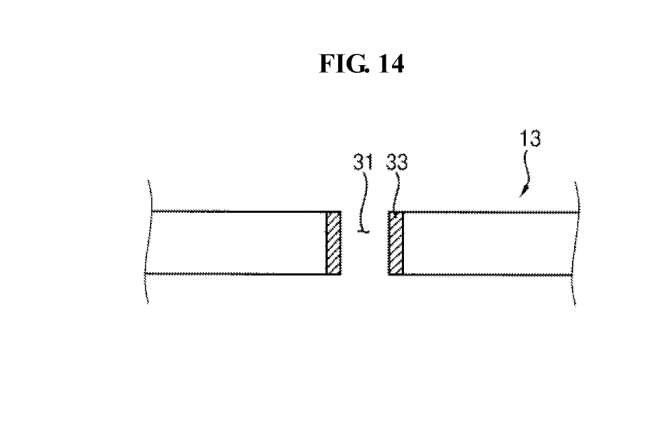

FIG. 14 is a view illustrating an example of the guide of FIG. 8.

Referring to FIG. 14, the probe card 100 of the present invention may have the guide 17, as described above, to align the vertical probes 11 that are moved when coming in contact with a circuit device. The guide 17 includes the first guides 13 and the second guides 15 and the materials and the structures are substantially similar, such that it is described below with reference to a first guide 13.

The first guide 13 may have a through-hole through which the contact portion 23 passes to expose the protrusions 29 and the second guide 15 may have a through-hole through which the transmitting portion 25 passes to expose the end of the transmitting portion 25.

The first guide 13 and the second guide 15 may be manufactured, using a silicon substrate, and the through-hole 31 of the first guide 13 and the through-hole of the second guide 15 may be formed by etching. Accordingly, the guide 17 of the present invention can be manufactured in large quantities.

The sides of the through-hole 31 of the first guide 13 and the through-hole of the second guide 15 need to be coated with an insulator. Accordingly, in the present invention, a coating layer 33 to be coated with an insulator may be formed on the sides of the through-hole 31 of the first guide 13 and the through-hole of the second guide 15. The insulator may be, for example, an oxide.

Forming the coating layer 33 is because the first guide 13 and the second guide 15 are made of a silicon substrate. That is, when the contact portion 23 and the transmitting portion 25 are brought in contact with the side of the through-hole of the first guide 13 and the side of the through-hole of the second guide, respectively, electricity is transmitted, such that the reliability of an electrical test using the probe card 100 may be influenced.

As described above, since the probe card of the present invention can be manufactured in a 2D structure or a 3D structure by MEMS, it can be more actively used for probing the micro-bump of recent circuit devices having fine pitch, such that it is possible to more actively meet the demand in the marker.

Further, since the probe card of the present invention has elastic protrusions made of an elastic material, damage to a bump is minimized. Accordingly, the probe card may not have a specific influence when coming in contact with the micro-bump of recent circuit devices having smaller shapes due to micro-bumps, such that it is possible to ensure competitiveness of a product by improving the reliability of an electrical test.

Further, since the probe card of the present invention can be made of a silicon substrate, it can be manufactured in large quantities, such that it is possible to ensure price competitiveness with reduction of manufacturing cost and time.

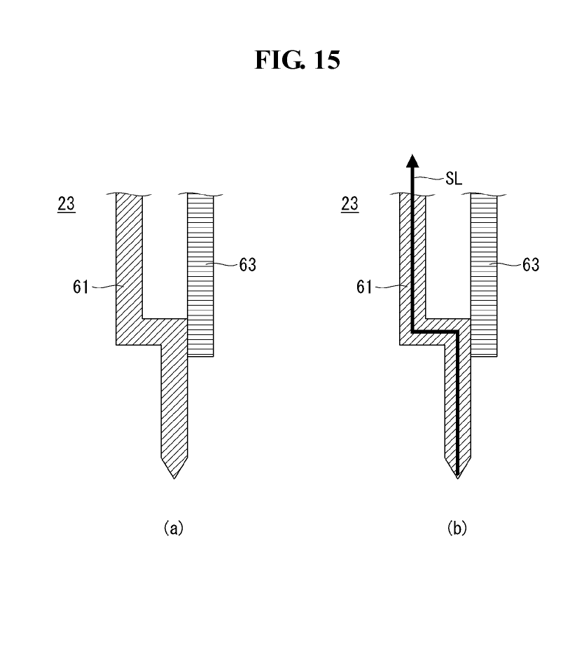

FIGS. 15 to 17 are views showing other embodiments of the vertical probe of FIG. 8.

As shown in the figures, the contact portion 23 of a vertical protrusion according to another embodiment of the present invention may have a complex structure. With the complex structure, it is possible to optimize the electric properties and/or the mechanical properties of the contact portion 23.

As shown in (a) of FIG. 15, the contact portion 23 may be composed of a first part 61 and a second part 63. That is, it means that one contact portion 23 may be at least partially different in structure and/or material. The first part 61 and the second part 63 may be combined by bonding and welding etc.

As shown in (b) of FIG. 15, the first part 61 may be made of a material considering the electric properties and the second part 63 may be made of a material considering the mechanical properties. That is, it means that the first part 61 may be made of a material that can transmit an electric signal SL from the end of the contact portion 23 without a loss and the second part 63 may be made of a material that can reinforce the entire strength of the contact portion 23. By using different materials for the contact portion 23, it is possible to achieve characteristics that cannot be achieved from one material.

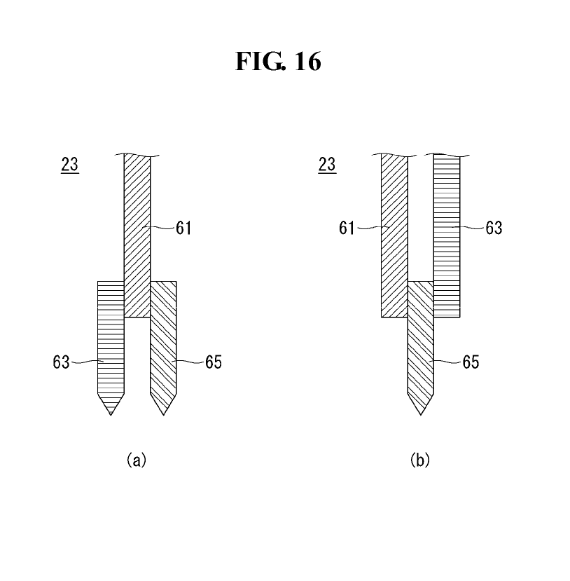

As shown in FIG. 16, the contact portion 23 may be formed in various shapes.

As shown in (b) of FIG. 16, the contact portion 23 may be composed of first to third part 61, 63, and 65. The first to third parts 61, 63, and 65 may be made of at least two materials.

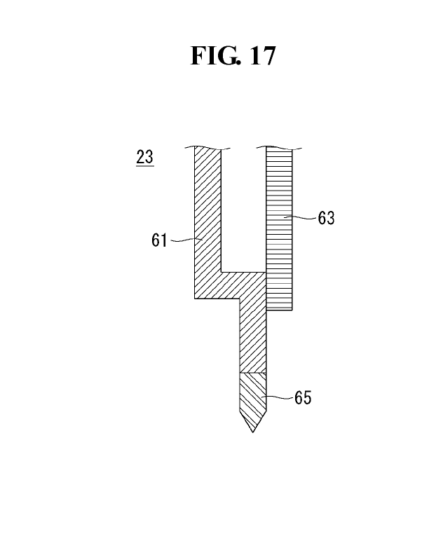

As shown in FIG. 17, the contact portion 63 may be made of different materials, depending on the positions. For example, the third part 65 may be the end of the contact portion 63 and may be made of a material different from that of the first part 61. The end of the contact portion 63 may be repetitively brought in contact with an object to be tested. Accordingly, the end of the contact portion 63 may be made of a material having excellent mechanical properties to resist wear and/or deformation.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A probe card comprising:
a printed circuit board;
a space transformer substrate that has a first side facing the printed circuit board and a second side opposite to the first side, has first circuit patterns on the second side, and has conductive signal transmitting portions that are filled in a plurality of through-holes formed through the first side and the second side and are connected with the first circuit pattern;
a plurality of connectors that connect the printed circuit board with the signal transmitting portions of the space transformer substrate; and
probe tips that have one end that can be brought in contact with an object to be tested and the other end that is connected to the first circuit patterns of the space transformer substrate.

2. The probe card of claim 1, wherein the space transformer substrate is made of ceramic.

3. The probe card of claim 1, further comprising a multilayer ceramic substrate disposed away from the printed circuit board and composed of several pattern layers,
wherein the multilayer ceramic substrate have second circuit patterns formed on the side facing the printed circuit board, and
the connectors connect the second circuit patterns with the printed circuit board.

4. The probe card of claim 1, wherein the connectors are any one of metal rods or metal wires or combinations of both of metal rods and metal wires.

5. The probe card of claim 1, wherein the first circuit patterns are formed in a shape corresponding to the probe tips, depending on any one or both of the arrangement of the probe tips and gaps therebetween.

6. The probe card of claim 1, wherein the first circuit patterns are formed such that electric properties between contact points that the probe tips are in contact with to the signal transmitting portions are uniform.

7. The probe card of claim 1, wherein the printed circuit board is protected by a reinforcing panel.

8. The probe card of claim 1, wherein the probe tip has:
a contact portion that is brought in electric contact with a micro-bump of a circuit device;
a transmitting portion that is disposed at the opposite side to the contact portion to interface an electric signal generated by electric contact with the micro-bump to a substrate thereon;
a connecting portion that has a vertical pole structure to connect the contact portion with the transmitting portion; and
protrusions that are formed to protrude from the surface of the vertical pole structure toward the micro-bump, at the corners of the end of the contact portion.

9. The probe card of claim 8, wherein the contact portion is made of a nickel alloy and the protrusions are made of at least one of rhodium, a carbon-plated material, and a rhodium-plated material.

10. The probe card of claim 8, wherein at least any one of the contact portion, the transmitting portion, the connecting portion, and the protrusions is made of a different from that of at least another one of the contact portion, the transmitting portion, the connecting portion, and the protrusions.
